(19) United States
(12) Patent Application Publication
(10) Pub. No.: US 2009/0033840 A1
(43) Pub. Date: Feb. 5, 2009

(54) CHIP MODULE, ACTIVE DEVICE ARRAY SUBSTRATE AND LIQUID CRYSTAL DISPLAY PANEL

(75) Inventors: Yi-Nan Chu, Changhua Hsien (TW); Wen-Tse Tseng, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taipei (TW)

(21) Appl. No.: 11/970,521

(22) Filed: Jan. 8, 2008

(30) Foreign Application Priority Data
Jul. 31, 2007 (TW) 96127940

(51) Int. Cl. G02F 1/1345; H01L 23/48; G02F 1/1335

(52) U.S. Cl. 349/106; 257/697; 257/72; 349/152; 257/E23.01

(57) ABSTRACT

An active device array substrate including a substrate, a pixel array, a plurality of first pads and a plurality of second pads is provided. The substrate has a display area and a peripheral area. Additionally, the pixel array is disposed within the display area. The first pads and the second pads are disposed within the peripheral area, and electrically connected to the pixel array respectively. Moreover, the first pads have a plurality of micro cavities.

### CROSS-REFERENCE TO RELATED APPLICATION

This application claims the priority benefit of Taiwan application serial no. 96127940, filed on Jul. 31, 2007. The entirety of the above-mentioned patent application is hereby incorporated by reference herein and made a part of this specification.

### BACKGROUND OF THE INVENTION

1. Field of the Invention

The present invention is related to a structure of a chip module and a liquid crystal display (LCD) panel, and particularly to a structure of pins of a chip module and pads of an LCD panel.

2. Description of Related Art

Nowadays, the multimedia technology has been very well developed, which mostly benefits from the progress made in semiconductor devices and display apparatuses. As for displays, LCDs with superior features such as high definition, good space utilization, low power consumption and no radiation have gradually become the mainstream of the market.

Specifically, an LCD is constituted by a thin film transistor, TFT) array substrate, a color filter substrate, and a liquid crystal layer sandwiched between the aforesaid two substrates. In the conventional fabricating process of LCDs, driving chips are adhered to pads on the TFT array substrate by a high-temperature compression process. Since a temperature at which a high-temperature compression process is performed to adhere the driving chips and the pads is generally 160-180° C. for a period about 10 seconds, each of the components inside the LCD may quite possibly be less reliable or be damaged because of the heat. Especially for optical films attached on an LCD, the optical films are quite easy to deteriorate because of high temperature such that the display quality and reliability of the LCD is significantly lowered.

### SUMMARY OF THE INVENTION

The present invention provides a chip module, which can be closely adhered to a surface of an object at a normal temperature.

The present invention provides an active device array substrate, which can be closely adhered to general chips at a normal temperature.

The present invention provides an LCD panel having superior reliability and display quality.

The present invention provides a chip module including a chip and a plurality of pins. The pins are disposed on the chip. At least one pin has a plurality of micro cavities.

According to one embodiment of the present invention, a width of each of the micro cavities may be smaller than 1 micrometer.

The present invention provides an active device array substrate including a substrate, a pixel array, a plurality of first pads and a plurality of second pads. The substrate has a display area and a peripheral area around the display area. In addition, the pixel array is disposed within the display area. The first pads are disposed within the peripheral area and electrically connected to the pixel array, and the first pads have a plurality of micro cavities. Furthermore, the second pads are disposed within the peripheral area and electrically connected to the pixel array.

According to one embodiment of the present invention, the second pads may have a plurality of micro cavities.

According to one embodiment of the present invention, a width of each of the micro cavities may be smaller than 1 micrometer.

According to one embodiment of the present invention, the pixel array may include a plurality of scan lines, a plurality of data lines and a plurality of pixel units. The pixel units are electrically connected to the respective scan lines and the respective data lines correspondingly.

The present invention provides an LCD panel including a substrate, a pixel array, a plurality of first pads, a plurality of second pads, a liquid crystal layer and an opposite substrate. The substrate has a display area and a peripheral area around the display area. Moreover, the pixel array is disposed within the display area. The first pads are disposed within the peripheral area and electrically connected to the pixel array, and the first pads have a plurality of micro cavities. Furthermore, the second pads are disposed in the peripheral area and electrically connected to the pixel array. The liquid crystal layer is sandwiched between the active device array substrate and the opposite substrate.

According to one embodiment of the present invention, the second pads may have a plurality of micro cavities.

According to one embodiment of the present invention, a width of each of the micro cavities may be smaller than 1 micrometer.

According to one embodiment of the present invention, the pixel array may include a plurality of scan lines, a plurality of data lines and a plurality of pixel units. The pixel units are electrically connected to the respective scan lines and the respective data lines correspondingly.

According to one embodiment of the present invention, the opposite substrate includes a color filter substrate.

According to one embodiment of the present invention, the opposite substrate includes a transparent substrate.

In the chip module of the present invention, since pins thereof have a plurality of micro cavities, they can be closely adhered to a surface of an object at a normal temperature so as to effectively prevent the chip module from being damaged because of the high temperature. The first pads of the active device array substrate in the present invention have micro cavities, and thus general chips can be adhered to the first pads under a normal temperature, and damage to each of the components in the LCD panel caused by high temperature is effectively avoided. The present invention provides an LCD panel having superior reliability and display quality.

In order to make the aforementioned and other objects, features and advantages of the present invention more comprehensible, preferred embodiments accompanied with figures are described in detail below.

### BRIEF DESCRIPTION OF THE DRAWINGS

FIG. 1 is a schematic view of the chip module according to the first embodiment of the present invention.

FIG. 2A is a schematic cross-sectional view of the LCD panel according to the second embodiment of the present invention.

FIG. 2B is a schematic top view of the active device array substrate according to the second embodiment of the present invention.

### DESCRIPTION OF EMBODIMENTS

### The First Embodiment

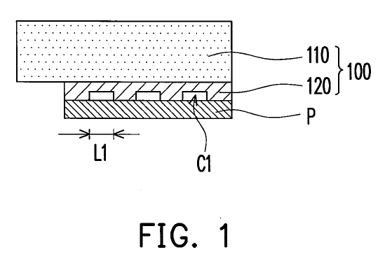

FIG. 1 is a schematic view of the chip module according to the first embodiment of the present invention. Referring to FIG. 1, a chip module 100 of the present invention includes a chip 110 and a plurality of pins 120. It is noted that only one pin 120 is shown in FIG. 1 for clear illustration. Specifically, the pin 120 is disposed on the chip 110 and can be electrically connected to the chip 110. Particularly, the pin 120 of the chip module 100 has a plurality of micro cavities C1. In practice, a width L1 of the micro cavity C1 may be smaller than 1 micrometer.

For example, the chip module 100 may be adhered to a general pad P through the pin 120 having the micro cavities C1. It should be noted that a hardness of a material of the pin 120 in the chip module 100 may be different from a hardness of a material of the pad P to be bonded with. Thus, when the pin 120 and the pad P are compressed together at a normal temperature, a pressure inside the micro cavity C1 is smaller than that of an external environment. As a result, the pin 120 and the pad P can be closely bonded together. Certainly, people of ordinary skill in the art should know that the chip module 100 of the present invention may also be adhered to a surface of other objects and is not limited to be adhered to the pad P.

It is noticed that since the chip module 100 of the present invention may be closely adhered to a desired object at a normal temperature, the chip module 100 of the present invention and the desired object to be adhered to need not be compressed together at a high temperature. Consequently, the reliability of each of the components in the chip module 100 is effectively prevented from deteriorating because damage to each of the components caused by high temperature is avoided. In order to increase the level of adhesion between the pin 120 and the pad P, the chip module 100 and the pad P of the present invention can be compressed under a low pressure or in a vacuum environment so that the reliability of the pin 120 and the pad P after adhesion is increased.

### The Second Embodiment

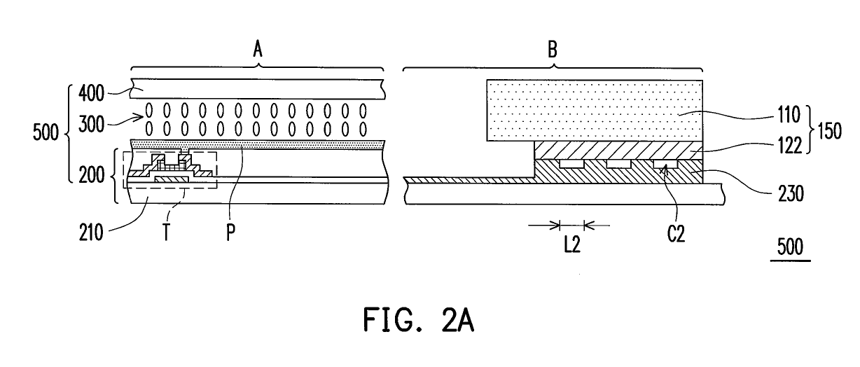

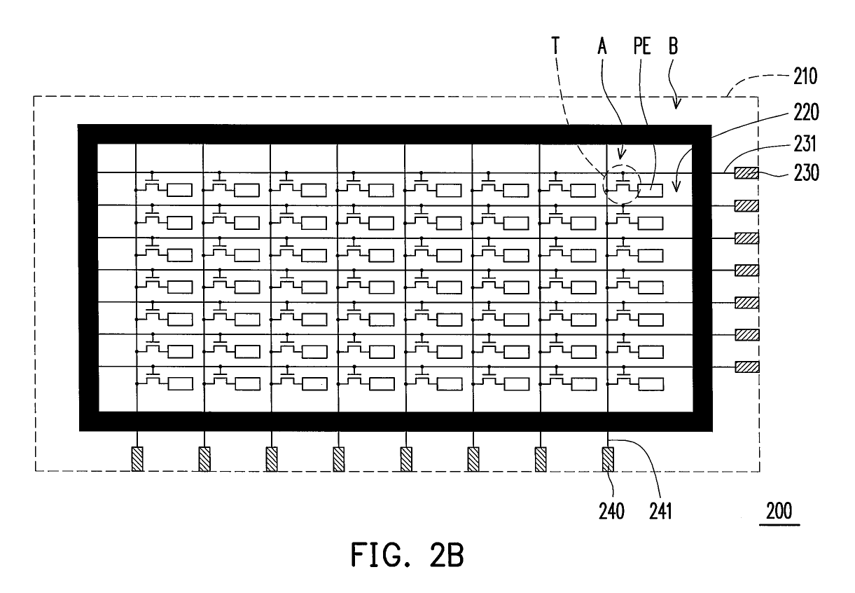

FIG. 2A is a schematic cross-sectional view of the LCD panel according to the second embodiment of the present invention. FIG. 2B is a top view of the active device array substrate according to the second embodiment of the present invention. Referring to both FIGS. 2A and 2B, an LCD panel 500 of the present invention mainly includes an active device array substrate 200, a liquid crystal layer 300 and an opposite substrate 400. The liquid crystal layer 300 is sandwiched between the active device array substrate 200 and the opposite substrate 400. Generally, the opposite substrate 400 may also be a color filter. Certainly, a transparent substrate may also be adopted as the opposite substrate 400, and the active device array substrate 200 may use the color filter on array (COA) technology but not limited to this combination.

Specifically, as illustrated in FIG. 2B, the active device array substrate 200 of the present invention includes a substrate 210, a pixel array 220, a plurality of first pads 230 and a plurality of second pads 240. The substrate 210 has a display area A and a peripheral area B around the display area. Moreover, a pixel array 220 is disposed within the display area A. The first pads 230 and the second pads 240 are disposed within the peripheral area B and electrically connected to the pixel array 220. The pixel array 220 may be constituted by a plurality of thin film transistors (TFTs) T and a plurality of pixel electrodes PE.

In practice, the first pads 230 may be electrically connected to the TFTs T through scan lines 231. The second pads 240 may be electrically connected to the pixel electrodes PE through data lines 241 and the TFTs T. Indeed, the first pads 230 and the second pads 240 may also be pads with other purposes on the active device array substrate 200, and are not specifically defined herein.

Specifically, referring to FIG. 2A, the active device array substrate 200 of the present invention may be electrically connected to a general chip module 150 through the first pads 230. The general chip module 150 may be a driving IC chip. The general chip module 150 is mainly constituted by the chip 110 and pads 122. It should be indicated that the first pads 230 have a plurality of micro cavities C2. In practice, a width of the micro cavity C2 may be smaller than 1 micrometer, and a profile thereof is merely adopted to facilitate illustration and not intended to limit the present invention. Certainly, the micro cavities C2 may also be optionally formed on the second pads 240 as illustrated in FIG. 2B, but are not specifically limited herein.

It should be indicated herein that a hardness of a material of the first pad 230 may be different from a hardness of a material of the pad 122 in the general chip module 150. Thus, when the first pads 230 and the pads 122 are compressed together at a normal temperature, a pressure inside the micro cavity C2 is smaller than that of an external environment. As a result, the first pads 230 and the pads 122 can be closely bonded together. In order to increase the level of adhesion between the first pads 230 and the pads 122 after adhesion, the active device array substrate 200 and the general chip module 150 of the present invention can be compressed under a low pressure or in a vacuum environment so that the reliability of the first pads 230 and the pads 122 after adhesion is increased.

Since the active device array substrate 200 and the general chip module 150 may be compressed together at a normal temperature, the problems of deteriorated reliability and damage in each of the components in the active device array substrate 200 and the general chip module 150 caused by a high temperature are effectively avoided. In other words, the reliability and the display quality of the LCD panel 500 of the present invention is significantly increased.

In conclusion, since the pins of the chip module in the present invention have a plurality of micro cavities, the chip module can be closely adhered to a surface of an object at a normal temperature so as to effectively prevent the chip module from being damaged because of the high temperature. Additionally, the active device array substrate is adhered to a general chip through the first pads and/or the second pads having micro cavities at a normal temperature so that each of the components in the LCD panel is prevented from being damaged due to the high temperature. Therefore, the LCD panel provided by the present invention has superior reliability and display quality.

Although the present invention has been disclosed above by the embodiments, they are not intended to limit the present invention. Anybody ordinarily skilled in the art can make some modifications and alterations without departing from the spirit and scope of the present invention. Therefore, the protecting range of the present invention falls in the appended claims.

What is claimed is:

1. A chip module, comprising:
a chip; and
a plurality of pins disposed on the chip, wherein at least one pin has a plurality of micro cavities.

2. The chip module as claimed in claim 1, wherein a width of each of the micro cavities is smaller than 1 micrometer.

3. An active device array substrate, comprising:
a substrate having a display area and a peripheral area around the display area;
a pixel array disposed in the display area;
a plurality of first pads disposed within the peripheral area and electrically connected to the pixel array, wherein each of the first pads has a plurality of micro cavities; and
a plurality of second pads disposed within the peripheral area and electrically connected to the pixel array.

4. The active device array substrate as claimed in claim 3, wherein the second pads have a plurality of micro cavities.

5. The active device array substrate as claimed in claim 3, wherein a width of each of the micro cavities is smaller than 1 micrometer.

6. The active device array substrate as claimed in claim 3, wherein the pixel array comprises a plurality of scan lines, a plurality of data lines and a plurality of pixel units, and the pixel units electrically connected to the respective scan lines and the respective data lines correspondingly.

7. A liquid crystal display (LCD) panel, comprising:
an active device array substrate, comprising:
a substrate having a display area and a peripheral area around the display area;
a pixel array disposed within the display area;
a plurality of first pads disposed within the peripheral area and electrically connected to the pixel array, wherein each of the first pads has a plurality of micro cavities;
a plurality of second pads disposed within the peripheral area and electrically connected to the pixel array;
an opposite substrate; and
a liquid crystal layer sandwiched between the active device array substrate and the opposite substrate.

8. The LCD panel as claimed in claim 7, wherein each of the second pads has a plurality of micro cavities.

9. The LCD panel as claimed in claim 7, wherein a width of each of the micro cavities is smaller than 1 micrometer.

10. The LCD panel as claimed in claim 7, wherein the pixel array comprises a plurality of scan lines, a plurality of data lines and a plurality of pixel units, and the pixel units electrically connected to the respective scan lines and the respective data lines correspondingly.

11. The LCD panel as claimed in claim 7, wherein the opposite substrate comprises a color filter substrate.

12. The LCD panel as claimed claim 7, wherein the opposite substrate comprises a transparent substrate.
